(19) United States
(12) Patent Application Publication
(10) Pub. No.: US 2010/0181670 A1
(43) Pub. Date: Jul. 22, 2010

(54) CONTACT STRUCTURE FOR A SEMICONDUCTOR AND METHOD FOR PRODUCING THE SAME

(76) Inventors: Andreas Krause, Dresden (DE); Bernd Bitnar, Freiberg (DE); Holger Neuhaus, Freiberg (DE); Martin Kutzer, Penig (DE)

Correspondence Address: MCGLEW & TUTTLE, PC, P.O. BOX 9227, SCARBOROUGH STATION, SCARBOROUGH, NY, 10510-9227, US

(21) Appl. No.: 12/602,232

(22) PCT Filed: Jun. 19, 2008
(86) PCT No.: PCT/EP2008/004960

§ 371 Date: Nov. 30, 2009

(30) Foreign Application Priority Data
Jul. 10, 2007 (DE) 102007031958.6

(51) Int. Cl. H01L 23/52; H01L 21/768

(52) U.S. Cl. 257/751; 438/653; 257/E23.141; 257/E21.584

(57) ABSTRACT

A semiconductor component comprising a substrate with a first side and a second side a multi-layer contact structure arranged on at least one side of the substrate, the contact structure exhibiting a barrier layer to prevent the diffusion of ions from the side of barrier layer opposite to the substrate into the substrate.

### BACKGROUND OF THE INVENTION

1. Field of the Invention

The invention relates to a semiconductor component and a method for producing such a semiconductor component.

2. Background Art

Solar cells usually have a front-side contact made of screen-printed silver fingers. These have a typical width of 100 to 120 μm and are about 10 to 15 μm thick. As it is not possible to reach much higher aspect ratios than about 0.1 using screen printing, the finger width cannot be reduced without at the same time increasing the line resistance of the fingers. On the other hand, the wider the front-side contacts, the higher the losses caused by the shading of the front side. Another disadvantage are the high material costs of the silver contacts.

Different methods for improving the contact technology for silicon substrate front contacts have already been described.

EP 1 182 709 A1 discloses a method for producing metal contacts in which trenches are arranged on the front side of a silicon substrate, which trenches accommodate a metal contact made of a nickel-copper layer system. A disadvantage of this method is the necessary tempering step after nickel precipitation.

DE 43 33 426 C1 describes a method for light-induced electroplating of silicon substrate contacts. Here, the rear contact of the silicon substrate serves as a sacrificial cathode. The chemicals used contain cyanide.

DE 43 11 173 A1 describes a method for direct electroplating on silicon surfaces. Here, the precipitation of a palladium seed layer is first required. On said layer, a nickel coating occurs, onto which the real current-carrying contact layer is precipitated.

DE 10 2004 034 435 B4 describes a method for the light-induced precipitation of a metal contact along an edge of a trench introduced into the surface of a semiconductor component.

U.S. Pat. No. 4,320,250 discloses a silicon substrate with a plurality of electrodes lying closely next to each other and consisting of several successive layers, which are first precipitated on the contact surfaces of the silicon substrate by means of conventional vacuum coating technology and which are then increased, in a further method step, by an electroplating process. This method is very elaborate.

DE 198 31 529 A1 relates to a method for producing an electrode, which is applied by electroforming or electrostatic powder coating on pointed or edge-shaped protrusions on a substrate surface. Thereafter, a series of chemical reactions and method steps are required to complete the electrode.

DE 195 36 019 B4 describes a method for producing fine, discrete metal structures, which are generated by means of photochemically assisted metal precipitation on a photovoltaically active semiconductor material, and are then detached from the substrate.

The known methods are elaborate and expensive.

### SUMMARY OF THE INVENTION

The invention is therefore based on the object of creating a favourably priced method for producing a contact structure with a high aspect ratio and a semiconductor component with a contact structure of such kind.

Said object is achieved by a semiconductor component according to the invention. The core of the invention consists in arranging between a semiconductor substrate and a conductor layer a barrier layer to prevent the diffusion of defect-causing ions from the conductor layer into the semiconductor substrate. This way, the selection of the materials available for the forming of the conductor layer is very much expanded. Moreover, this way a contact structure with a high aspect ratio can be achieved, which reduces the losses due to the shading of the front side by the contact structure.

Features and details of the invention result from the description of embodiments based on the drawings.

### BRIEF DESCRIPTION OF THE DRAWINGS

FIG. 1 shows a schematic cross-section, not to scale, through a semiconductor component with applied conductor paths prior to the application of a barrier layer,

FIG. 2 shows a cross-section according to FIG. 1 after the application of a barrier layer but prior to the application of a conductor layer,

FIG. 3 shows a cross-section according to FIG. 2 after the application of a conductor layer but prior to the application of a protective layer,

FIG. 4 shows a cross-section according to FIG. 3 but after the application of a protective layer,

FIG. 5 shows a schematic representation of the method for producing a semiconductor component according to FIGS. 1 to 4 and

FIG. 6 shows a schematic cross-section, not to scale, through another embodiment of a semiconductor component before the application of conductor paths.

### DESCRIPTION OF THE PREFERRED EMBODIMENTS

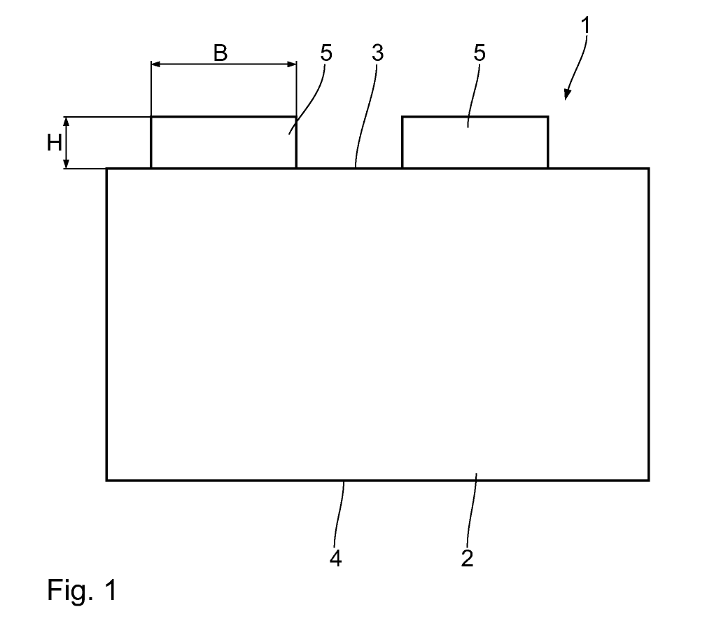

In the following, a semiconductor component according to the present invention is described with reference to FIGS. 1 to 4. As a starting point, a semiconductor component 1 exhibits a substrate 2. Especially a silicon substrate serves as a substrate 2. Another semiconductor substrate may, however, also serve as a substrate 2. Substrate 2 is essentially of a planar design with a first side and a second side lying opposite thereto, the first side forming a front side 3, while the second side forms a rear side 4 of the substrate 2. The substrate 2 consists at least partly of silicon. On the front side 3 of the substrate 2 there is envisaged a plurality of conductor paths 5. The conductor paths 5 have side shoulders 16, which enclose an angle b with the front side 3 of the substrate 2. The angle b is at least 90°. The angle b is especially greater than 90°, especially greater than 100°. The shoulders 16 of the conductor path 5 are thus preferably made to converge towards each other, which leads to particularly little shading. The conductor paths 5 may, however, also be arranged on the rear side 4. The conductor paths 5 are in electrical contact with the substrate 2. The conductor paths 5 are of an electrically conductive material, especially a metal that exhibits a particularly low diffusion coefficient with regard to the material of the substrate 2. The conductor paths 5 especially exhibit a high silver content. They may also be made fully of pure silver. The conductor paths 5 have a width B parallel to the front side 3 of the silicon substrate 2, which is as small as possible in order to reduce shading of the front side 3 by the conductor paths 5. The conductor paths 5 have a height H vertically to the front side 3, which is a large as possible to reduce the line resistance of the conductor paths 5. The conductor paths 5 thus protrude from the front side 3 by the height H. The side shoulders 16 are thus exposed along their full extension. The width B of the conductor paths 5 is usually in the range of 10 μm to 200 μm, especially in the range of 100 μm to 120 μm. The height H of the conductor paths 5 is usually in the range of 1 μm to 50 μm, especially in the range of 5 μm to 15 μm. The aspect ratio AV_{Lb}=H/B, defined as height versus width, of the screen-printed conductor paths 5 is about 0.1. Such conductor paths 5 usually have a line resistance R_{1f} of about 40 Ω/m. The line resistance R_{1f} can, however, be much higher.

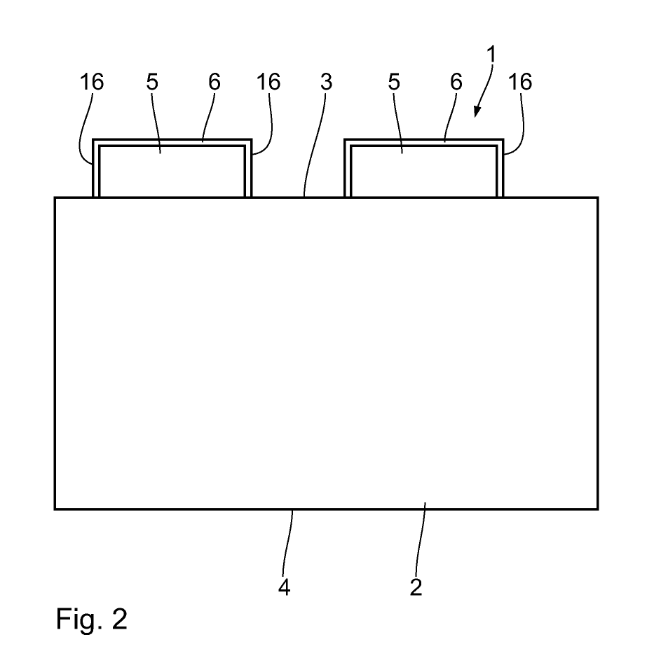

According to a first method step, the semiconductor component 1 exhibits a barrier layer 6, as shown in FIG. 2. The barrier layer 6 encloses especially the conductor path 5. The thickness of the barrier layer 6 is 0.1 to 5 μm, especially 0.2 to 1 μm. The barrier layer 6 is from a material, especially a metal that has a negligible diffusion coefficient or a negligible mixibility with regard to the material of the conductor paths 5 and the conductor layer 7. The barrier layer 6 is especially made of electrolytically or chemically applied cobalt. It can also consist of nickel that has been applied electrolytically. Other materials are also conceivable. The barrier layer 6 has an advantageously high electrical conductivity. Advantageously, the metal of the barrier layer can be stripped well electromechanically for the cleaning of the contact rollers. This applies in particular to cobalt.

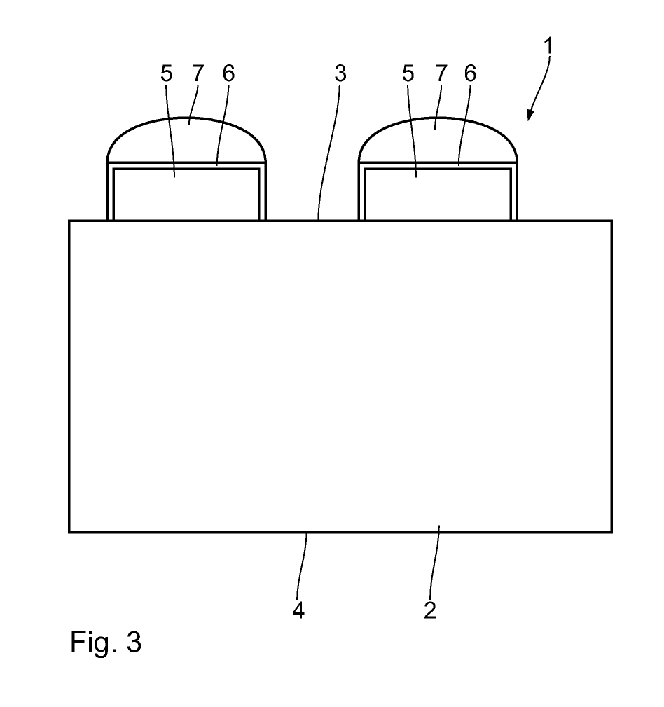

According to a further method step, the semiconductor component 1 exhibits a conductor layer 7, as shown in FIG. 3. The conductor layer 7 is made of copper. The conductor layer 7 can at least partly also consist of another material with a high electrical conductivity. The conductor layer 7 is especially made of a material that exhibits a very low partial diffusion coefficient with regard to the material of the barrier layer 6. Advantageously, only a low mixability exists between the material of the barrier layer 6 on the one hand and the material of the conductor layer 7 on the other hand.

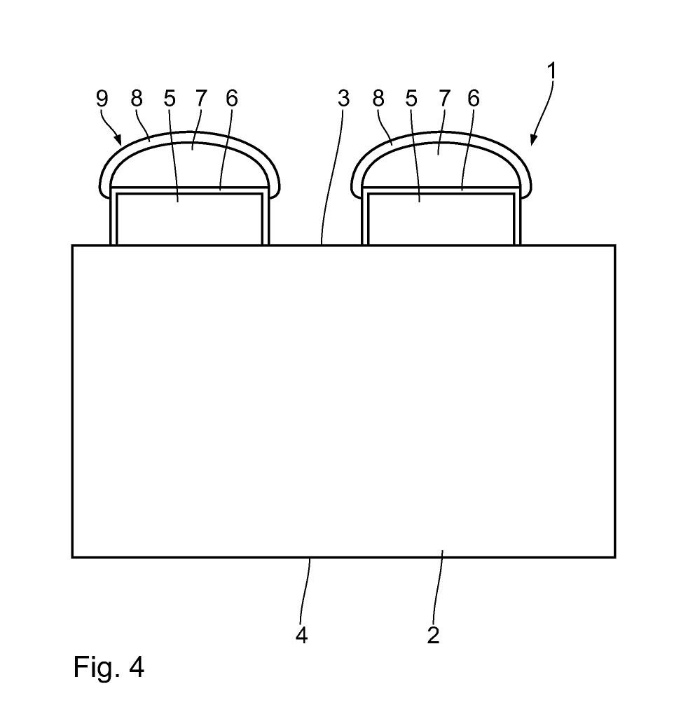

According to a further method step, the semiconductor component 1 also exhibits a protective layer 8, as shown in FIG. 4. The protective layer 8 encloses the conductor layer 7. The protective layer 8 is especially made of silver. It may also be made of tin. The protective layer 8 is corrosion-protective.

Collectively, the conductor paths 5, the barrier layer 6, the conductor layer 7 and the protective layer 8 form a multi-layer contact structure 9. The contact structure 9 thus especially has a four-layer design. The individual layers of the contact structure 9 essentially exhibit the same width B as the conductor paths 5. The height of the contact structure 9, however, is the sum of the heights of the conductor paths 5, the barrier layer 6, the conductor layer 7 and the protective layer 8. The contact structure 9 thus exhibits an aspect ratio AV_{KS}, which is greater than the aspect ratio AV_{Lb} of the conductor paths 5. Here, especially the following is true: AV_{KS}/AV_{Lb}≧1.5, especially AV_{KS}/AV_{Lb}≧2, especially AV_{KS}/AV_{Lb}≧4. Accordingly, the line resistance R_{KS} of the individual paths of the contact structure 9 is lower than the line resistance R_{1f} of the conductor paths 5. Here, especially the following is true: R_{KS}/R_{1f}≦0.5, especially R_{KS}/R_{1f}≦0.3, especially R_{KS}/R_{1f}≦0.2.

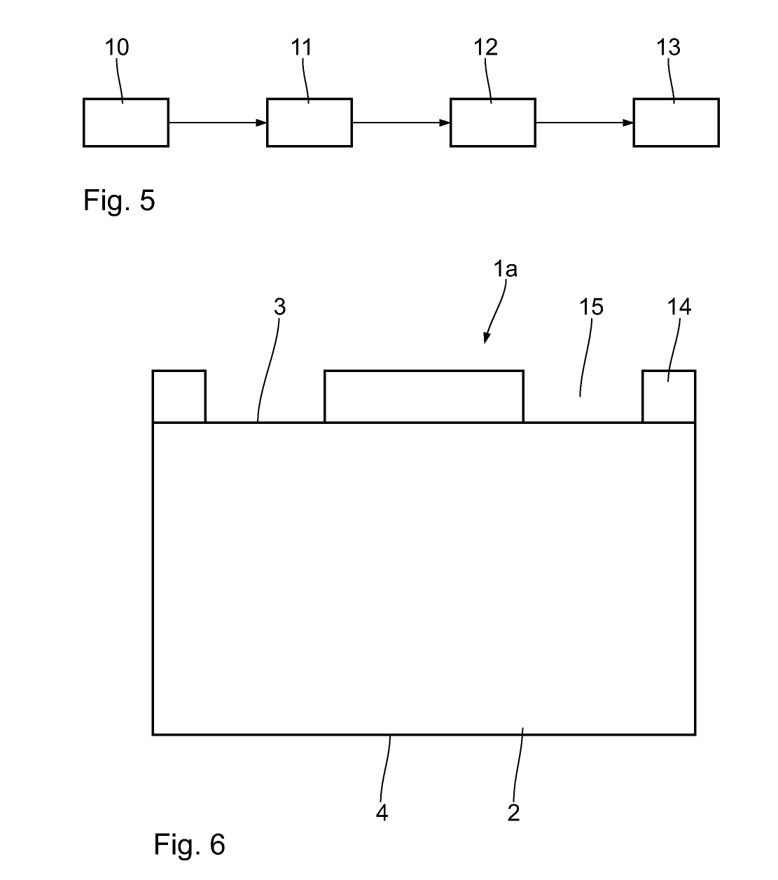

In the following there is described with reference to FIG. 5 the method for producing the semiconductor component 1, especially for producing the contact structure 9. In a first method step 10, the substrate 2 is made available and provided with the conductor paths 5 on the front side 3 by means of a screen-printing method. The conductor paths 5 can also be arranged on the rear side 4 or on both sides 3, 4 of the substrate 2.

In a further method step, a first electrolytic precipitation 11, the substrate 2, especially the conductor paths 5, is coated with the barrier layer 6. To this end, cobalt or nickel are electrolytically precipitated on the substrate 2 and the conductor paths 5. Thanks to the galvanic coating, a good adhesion of the barrier layer 6 on the substrate 2 and den conductor paths 5 is achieved, without the need to interrupt the wet-chemical method by a tempering step. This enables a particularly low-cost method. The electrolytic precipitation of the barrier layer 6 occurs especially in Watts-type baths, which exhibit a moderately acidic pH value, especially pH 3 to 5. These baths do not attack the conductor paths 5. Other baths with a pH value greater than pH 3 may also be used. The electrical potential for the electrolytic precipitation of the barrier layer 6 can be generated by irradiation of the substrate 2 with light of a suitable wavelength and intensity. Moreover, the electrical resistance of the substrate can be reduced though this measure.

In a further method step, a second electrolytic precipitation 12, the conductor layer 7 is applied onto the barrier layer 6. To this end, the semiconductor component 1 is immersed in an acidic copper bath in a potential-controlled manner, i.e. the potential is already applied before the wafers are immersed in the bath. During the second electrolytic precipitation 12, the approx. 10 μm thick conductor layer 7 is precipitated on the conductor paths 5, but separated therefrom by the barrier layer 6. The electrolytical application of the conductor layer 7 during the second electrolytic precipitation 12 occurs especially by means of a pulse plating method, during which there is periodic switching between anodic and cathodic potentials. As result, there is periodic switching of electrolytic precipitation and dissolution on the conductor paths. Moreover, the pulse plating method enables the precipitation of very stress-relieved layers. Since the field strengths are higher on the edges of the conductor paths 5, the dissolution rate there is also higher, which counteracts a broadening of the conductor paths 5. Electrolytic precipitation may be assisted by irradiation with light of a suitable intensity and wavelength.

In a further method step, a protective coating 13, the semiconductor component 1 is briefly immersed in a silver bath in order to coat the conductor layer 7 applied onto the conductor paths 5 in the second electrolytic precipitation 12 with the corrosion-protective layer 8 made of silver. As an alternative, the protective coating 13 may also be envisaged by means of a more low-cost electrolytic precipitation of tin.

The contact structures 9 produced according to the invention have stabile layers. Pull-off tests have shown a very good adhesive strength of the contact structures 9 on the silicon substrate 2. The electric losses in the individual paths of the contact structure 9 are greatly reduced compared to those of the conductor paths 5. On the whole, the method according to the invention leads to an enlarged aspect ratio AV_{KS} of the individual paths of the contact structure 9, which in turn leads to an increase in efficiency of a solar cell with that kind of contact structures 9. The method steps 11, 12 and 13 can be realised as a continuous method, i.e. the wet-chemical or electrochemical method steps 11,12 and 13 do not have to be interrupted by a tempering step. As a result, the method is an especially low-time and low-cost method.

In the following, a further embodiment of the semiconductor component la is described with reference to FIG. 6a. Identical parts receive the same reference number as for the embodiment, reference to the description of which is hereby made. The central difference from the first embodiment consists in that the substrate 2 is first provided with an isolating layer 14. The isolating layer 14 is e.g. made of silicon nitride or silicon dioxide. At the locations where the barrier layer 6 and the conductor layer 7 are to be arranged, the isolating layer 14 is selectively provided with contact openings 15. The application of conductor paths 5 can be dispensed with. A laser-, plasma- or a wet-chemical or a paste etching process is envisaged for the production of the contact openings 15 in the isolating layer 14. After the opening of the isolating layer 14, the barrier layer 6 and the conductor layer 7 can be applied according to the first embodiment.

On this embodiment the barrier layer 6 is in direct contact with the substrate 2. It prevents the diffusion of metal from the conductor layer 7 into the substrate 2. Moreover, it ensures good adhesion of the conductor layer 7 on the substrate 2.

In another embodiment, a palladium seed layer with thickness of a few nanometres is applied onto the substrate in the locations where the barrier layer 6 and the conductor layer 7 are to be arranged. As a result, the seed formation work is reduced such that a homogeneous barrier layer 6 made of nickel, cobalt or a nickel-cobalt alloy can be galvanically applied directly and without the support of light. Of course, palladium seeding may also be dispensed with, if galvanic precipitation of the barrier layer 6 is performed with the support of light. Since the barrier layer 6 consists, in any case, of ferromagnetic metals, it is envisaged, according to the invention, to reduce the seed formation work for electrocrystallisation through superimposition of an inhomogeneous magnetic field and to thus galvanically precipitate a homogeneous barrier layer 6 directly into the openings 15 of the isolating layer 14.

1. A semiconductor component comprising:
a substrate with a first side and a second side and a multi-layer contact structure arranged on at least one side of the substrate, the contact structure exhibiting a barrier layer to prevent the diffusion of ions from the side of barrier layer facing away from the substrate into the substrate.

2. A semiconductor component according to claim 1, wherein the contact structure exhibits a plurality of conductor paths, which protrude from the first side of the substrate by a height H.

3. A semiconductor component according to claim 2, wherein the height H of the conductor paths lies in the range of 1 μm to 50 μm.

4. A semiconductor component according to claim 1, wherein the barrier layer is at least partly made of at least one of cobalt and nickel.

5. A semiconductor component according to claim 1, wherein the barrier layer exhibits a thickness of 0.1 μm to 5 μm.

6. A semiconductor component according to claim 1, wherein the contact structure comprises a conductor layer arranged on the barrier layer.

7. A semiconductor component according to claim 6, wherein the conductor layer is at least partly made of copper.

8. A semiconductor component according to claim 1, wherein the contact structure exhibits an aspect ratio AV_{KS} of at least 0.1.

9. A semiconductor component according to claim 2, wherein the conductor paths exhibit an aspect ratio AV_{Lb} and wherein the contact structure exhibits an aspect ratio AV_{KS} whereby the following applies: AV_{KS}/AV_{Lb}≧1, 5.

10. A method for producing a semiconductor component according to claim 1, the method comprising the following steps:
provision of a substrate;
application of a barrier layer onto the substrate; and
application of a conductor layer onto the barrier layer.

11. A method according to claim 10, wherein the substrate is, in a first method step, provided with conductor paths.

12. A method according to claim 10, wherein the application of at least one of the layers occurs by means of electrolytic precipitation.

13. A method according to claim 10, wherein the application of at least one of the layers occurs by means of light-induced electroplating.

14. A method according to claim 13, wherein the application of the barrier layer onto the substrate, the application of the conductor layer onto the barrier layer and the application of a protective layer is realized as a continuous method not interrupted by tempering steps.

15. A method according to claim 10, wherein the application of the barrier layer is supported by superimposition of an inhomogeneous magnetic field.

16. A semiconductor component according to claim 2, wherein the height H of the conductor paths lies in the range of 5 μm to 15 μm.

17. A semiconductor component according to claim 1, wherein the barrier layer exhibits a thickness of 0.2 μm to 1 μm.

18. A semiconductor component according to claim 1, wherein the contact structure exhibits an aspect ratio AV_{KS} of at least 0.2.

19. A semiconductor component according to claim 1, wherein the contact structure exhibits an aspect ratio AV_{KS} of at least 0.4.

20. A semiconductor component according to claim 2, wherein the conductor paths exhibit an aspect ratio AV_{Lb} and wherein the contact structure exhibits an aspect ratio AV_{KS} whereby the following applies: AV_{KS}/AV_{Lb}≧2.

21. A semiconductor component according to claim 2, wherein the conductor paths exhibit an aspect ratio AV_{Lb} and wherein the contact structure exhibits an aspect ratio AV_{KS} whereby the following applies: AV_{KS}/AV_{Lb}≧4.
